(19) United States
(12) Patent Application Publication
(10) Pub. No.: US 2007/0010041 A1
(43) Pub. Date: Jan. 11, 2007

(54) Method of manufacturing optical device having transparent cover and method of manufacturing optical device module using the same

(75) Inventors: Suk-Chae Kang, Yongin-si (KR); Yong Chai Kwon, Suwon-si (KR); Yong-Hwan Kwon, Suwon-si (KR); Gu-Sung Kim, Seongnam-si (KR); Sun-Wook Heo, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/482,774

(22) Filed: Jul. 10, 2006

(30) Foreign Application Priority Data
Jul. 11, 2005 (KR) 10-2005-0062125

(51) Int. Cl. H01L 21/00

(52) U.S. Cl. 438/64; 438/66; 438/68; 438/73

(57) ABSTRACT

Example embodiments of the present invention relate to a method of manufacturing an optical device having a transparent cover and a method of manufacturing an optical device module using the optical device. According to an example method of manufacturing the optical device, a semiconductor substrate having a plurality of dies including an effective pixel and a plurality of bonding pads arranged around the effective pixel is prepared. A protective layer may be formed on the semiconductor substrate to selectively cover the effective pixel. An adhesive pattern may be formed to enclose an edge of the effective pixel, and a transparent cover may be attached to correspond to the effective pixel using the adhesive pattern.

### PRIORITY STATEMENT

This application claims the benefit of priority from Korean Patent Application No. 10-2005-0062125, filed on Jul. 11, 2005, in the Korean Intellectual Property Office, the disclosure of which is incorporated herein in its entirety by reference.

### BACKGROUND OF THE INVENTION

1. Field of the Invention

Example embodiments of the present invention relate to a method of manufacturing an optical device having a transparent cover and a method of manufacturing an optical device module using the optical device.

2. Description of the Related Art

In addition to digital cameras, many mobile electronic products such as cellular phones and personal digital assistants (PDAs) may be used to take digital photos. Particularly, in the case of a palm-sized apparatus such as a PDA and a cellular phone having a built-in digital camera, the quality of the apparatus is mainly determined by the characteristics of the built-in digital. An image sensor module processing an external image into digital signals has become one of the most important elements of such mobile electronic products.

As disclosed by the conventional art, a general image sensor module may include an image sensor mounted on a printed circuit board (PCB), a transparent cover, and a lens. The transparent cover and the lens may be fixed on the PCB with a housing and a lens holder. The housing may include an opening to expose a light-receiving plane of the image sensor, and the transparent cover may be mounted on the opening. The outer wall of the lens holder and the inner wall of the housing may be threaded, so that the housing and the lens may be screw-coupled, and the lens may be provided in the lens holder to correspond to the light-receiving plane.

The above image sensor module generally has a large volume due to the housing and lens holder. It may not be easy to use the prior art image sensor module to manufacture a small and slim mobile electronic apparatus. Also, as the housing and the lens holder are screw-coupled, an image sensing operation may be fatally affected by particles generated due to friction between the housing and the lens holder.

To address these problems, a technology has been developed in which a transparent cover may be attached on a wafer using an adhesive pattern instead of fixing the transparent cover on the wafer using the housing. Because the housing fixing the transparent cover is not required, the thickness of the image sensor module decreases with the height of the housing. Also, because the wafer may be covered with the transparent cover, the surface of the wafer may be protected from particles generated in a process of manufacturing the image sensor module.

It has been observed that, in prior art methods of attaching a transparent cover, a residual material of the adhesive pattern remains on an upper portion of the wafer, particularly, on the surface of a microlens, when the adhesive pattern is formed to attach the transparent cover. When an ashing or a descum process is performed to remove this residual material, the microlens (made for example of a photoresist, which is a similar ingredient to an adhesive layer made of a photosensitive polymer) is simultaneously removed, which causes a defect of the image sensor.

An image sensor, e.g., an optical device, that may be manufactured in a smaller and slimmer size at low costs, while preventing defects of the image sensor, a module of the image sensor, and a technology of manufacturing the same are highly desired.

### SUMMARY OF EXAMPLE EMBODIMENTS

Example embodiments of the present invention relate to a method of manufacturing an optical device having a transparent cover and a method of manufacturing an optical device module using the optical device.

Example embodiments of the present invention provide a method of manufacturing an optical device by which a residual material may be removed from a lens surface with minimal affect on the lens. Example embodiments of the invention also provide a method of manufacturing both an optical device in large quantities at lower cost per unit and an optical device module having a smaller size and a slimmer profile.

According to example embodiments of the present invention, there is provided a method of manufacturing an optical device, the method including: preparing a semiconductor substrate having a plurality of dies including an effective pixel and a plurality of bonding pads arranged around the effective pixel; coating a protective layer on the semiconductor substrate to selectively cover the effective pixel; forming an adhesive pattern to enclose an edge of the effective pixel; and attaching a transparent cover to allow the transparent cover to face the effective pixel using the adhesive pattern.

According to another example embodiment of the present invention, there is provided a method of manufacturing an optical device, the method including: preparing a semiconductor substrate having a plurality of dies including an effective pixel, and a plurality of bonding pads arranged around the effective pixel; forming a protective layer on the semiconductor substrate to selectively cover only the effective pixel; forming an adhesive pattern to enclose the effective pixel; and removing a residual material of the adhesive pattern remaining on the protective layer. The protective layer may protect a structure constituting the effective pixel when the residual material of the adhesive pattern is removed. A transparent cover may then be preliminarily attached on normal dies from among the dies, and the semiconductor substrate may be cured to collectively and permanently attach a plurality of transparent covers on the respective dies of the semiconductor substrate.

The effective pixel may include a plurality of unit pixels each containing a light-receiving device, and a microlens placed upon each of the unit pixels.

The protective layer may be deposited on a resulting structure surface of the effective pixel without transforming the shape of an ingredient constituting the effective pixel, and a transparent layer may be deposited along the surface of the effective pixel so as not to transform the curvature of the microlens. Also, the protective layer, e.g., the transparent layer, may be an oxide layer deposited in an approximate temperature range of 100-200° C., and a method of depositing the protective layer may be chemical vapor deposition (CVD) or atomic layer deposition (ALD).

Also, the adhesive pattern may be a photosensitive polymer material having a thickness of about 10 μm-30 μm, and the adhesive pattern may be obtained by exposing and developing an adhesive layer.

The method may further include, between the forming of the adhesive pattern and the preliminarily attaching of the transparent cover, inspecting whether the die has been normally formed.

Also, the preliminarily attaching of the transparent cover may include aligning the transparent cover with the effective pixel of the die using a die bonder; and placing the aligned transparent cover on the adhesive pattern. While placing the transparent cover, the substrate may be maintained in an approximate temperature range of 10-100° C., and the transparent cover may be maintained in an approximate temperature range of 100-300° C. Also, the hardening of the semiconductor substrate may include hardening the semiconductor substrate in an oven having an approximate temperature range of 100-250° C. for about 30-90 minutes.

According to another example embodiment of the present invention, there is provided a method of manufacturing an optical device module, the method including: preparing a semiconductor substrate having a plurality of dies including an effective pixel, and a plurality of bonding pads arranged around the effective pixel; forming a protective layer to selectively cover only the effective pixel; forming an adhesive pattern to enclose the effective pixel; attaching a transparent cover to allow the transparent cover to correspond to the effective pixel using the adhesive pattern; sawing the semiconductor substrate into individual dies; mounting the individual dies on a printed circuit board (PCB); electrically connecting each with the PCB; and placing a lens on the PCB.

### BRIEF DESCRIPTION OF THE DRAWINGS

Example embodiments of the present invention will be more clearly understood from the following brief description taken in conjunction with the accompanying drawings. FIGS. 1-3C represent non-limiting, example embodiments of the present invention as described herein.

FIG. 1 is a diagram illustrating a plan view of a semiconductor wafer where an image sensor is formed according to example embodiments of the present invention;

FIGS. 2A through 2F are diagrams illustrating sectional views along a line II-II′ of FIG. 1; and

FIGS. 3A through 3C are diagrams illustrating sectional views for illustrating a method of manufacturing an image sensor module according to example embodiments of the present invention.

### DETAILED DESCRIPTION OF EXAMPLE EMBODIMENTS

Various example embodiments of the present invention will now be described more fully with reference to the accompanying drawings in which some example embodiments of the invention are shown. In the drawings, the thicknesses of layers and regions may be exaggerated for clarity.

Detailed illustrative embodiments of the present invention are disclosed herein. However, specific structural and functional details disclosed herein are merely representative for purposes of describing example embodiments of the present invention. This invention may, however, be embodied in many alternate forms and should not be construed as limited to only the embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention. Like numbers refer to like elements throughout the description of the figures.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the scope of example embodiments of the present invention.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Spatially relative terms, such as “beneath”, “below”, “lower”, “above”, “upper” and the like, may be used herein for ease of description to describe one element or a feature's relationship to another element or feature as illustrated in the Figures. It will be understood that the spatially relative terms are intended to encompass different orientations of the device in use or operation in addition to the orientation depicted in the Figures. For example, if the device in the Figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Example embodiments of the present invention are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments of the invention should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope of the present invention.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments of the present invention belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments of the present invention, various aspects of the present invention will be described in detail with reference to the attached drawings. However, the present invention is not limited to example embodiments described.

Example embodiments of the present invention relate to a method of manufacturing an optical device having a transparent cover and a method of manufacturing an optical device module using the optical device.

Example embodiments of the present invention depict a method of attaching a transparent cover onto the structure of an image device covered with a protective layer. During a process of forming an adhesive layer for attaching the transparent cover, the remainder of the adhesive material may be prevented from remaining on the resulting structure of the image device.

Example embodiments of the present invention depict a method in which transparent covers are preliminarily attached onto the respective dies of a wafer and the resulting structure of the wafer is heated in an oven, thereby permanently attaching the transparent covers onto the wafer. The transparent covers may be simultaneously attached onto the wafer without using a costly wafer bonder for a longer period of time.

The optical device is an image sensing device that may be used to sense an image in video cameras, electronic still cameras, personal computers (PCs) cameras, terminals, PDAs or other similar devices. For example, the image sensing device may be a complementary metal-oxide semiconductor (CMOS) image sensor, a charge coupled device (CCD) image sensor, or a CMOS image sensor (CIS) onto which a pyroelectric ceramic may be introduced.

A method of manufacturing the above optical device and a method of manufacturing an optical device module will now be described in detail with reference to the accompanying drawings.

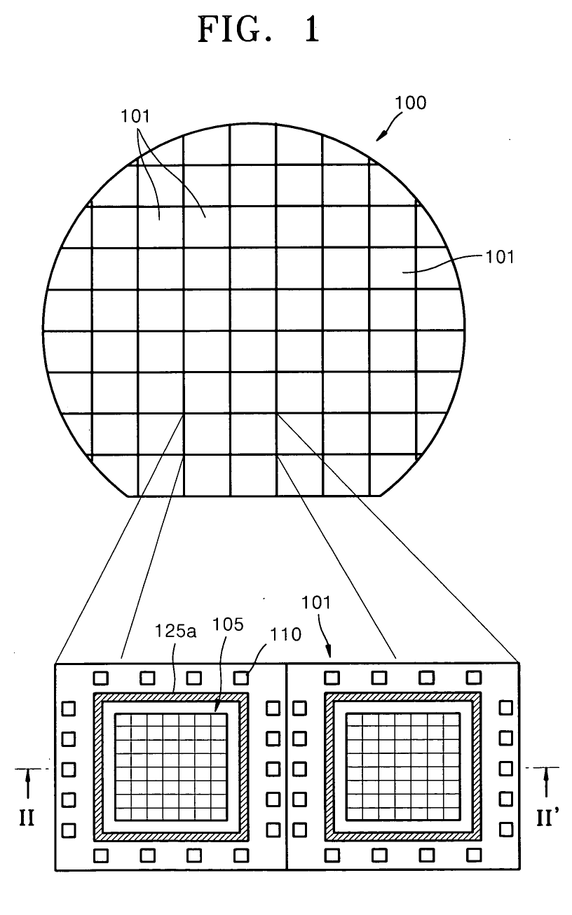

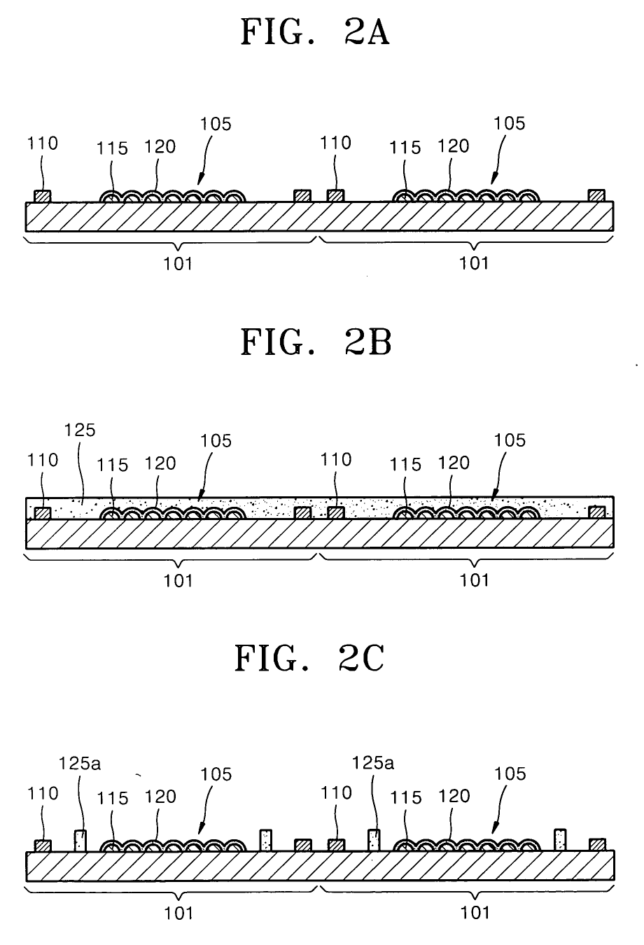

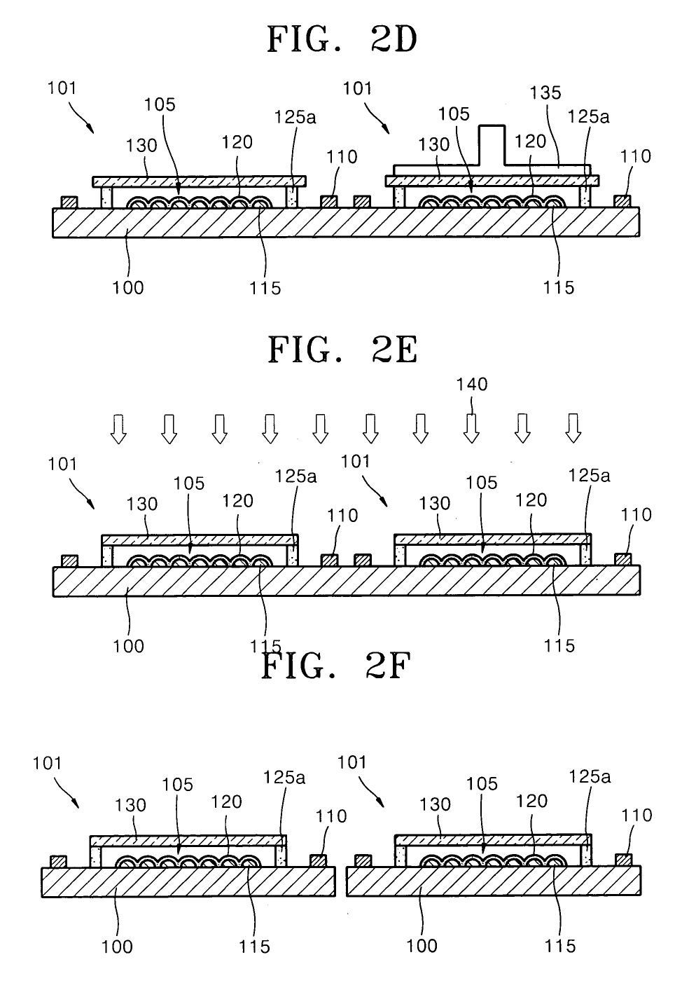

FIG. 1 is a diagram illustrating a plan view of a semiconductor wafer where an optical device, such as an image sensor, may be formed according to example embodiments of the present invention. A pair of dies constituting the semiconductor wafer is illustrated in the lower part of FIG. 1. FIGS. 2A through 2F are diagrams illustrating sectional views along line II-II″ of FIG. 1 and a method of manufacturing an optical device according to example embodiments of the present invention.

Referring to FIG. 1, a semiconductor substrate 100 may include a plurality of dies 101. Each of the dies 101 may include an image device, which may refer to an effective pixel 105 having a plurality of unit pixels; and a plurality of bonding pads 110 may be arranged around the effective pixel 105. The effective pixel 105 may include a light-receiving device (not illustrated) such as a photodiode; a plurality of transistors transferring electrons generated from the photodiode; and interconnection metal lines electrically connecting the transistor. The interconnection metal lines may be formed at an edge of the photodiode such that a maximum amount of light may be condensed on the photodiode. The effective pixel 105 may further include a microlens 115, which is provided in a region corresponding to the photodiode in order to enhance the condensing efficiency. The microlens 115 may be formed per unit pixel on the semiconductor substrate 100. The microlens 115 may exactly cover the light-receiving device. In other example embodiments, the microlens 115 may cover a portion of the light-receiving device such that it may also condense light that is incident at a dead angle. The microlens 115 may be formed using a process of forming a photoresist pattern and a process of heating the photoresist pattern at a temperature of about 200° C. to harden the photoresist pattern while forming a curvature. The microlens 115 may be formed to a height of about 4 μm-6 μm. The bonding pad 110 is formed, spaced apart from the effective pixel 105 by a desired distance. The microlens 115 may be formed simultaneously with interconnection metal lines in the effective pixel 105.

Referring to FIGS. 1 and 2A, a protective layer 120 may be formed on the surface of the effective pixel 105 where the microlens 115 may have been formed. The protective layer 120 should be formed at a low temperature of, e.g., 100 to 200° C., in order not to deform the microlens 115. Also, the protective layer 120 should be formed along the surface of the microlens 115 such that the curvature of the microlens 115 does not change. Also, the protective layer 120 should be transparent such that light may pass through the protective layer 120. The protective layer 120 may include a low-temperature oxide layer. For example, the low-temperature oxide layer may be formed by chemical vapor deposition (CVD) or atomic layer deposition (ALD). For example, the low-temperature oxide layer may be formed to a thickness of 10 Å to 1000 Å. After the protective layer 120 is deposited on the resulting structure of the semiconductor substrate 100, a well-known photolithography process may be performed on the deposited protective layer 120 such that the protective layer 120 remains on the effective pixel 105.

Referring to FIGS. 1 and 2B, an adhesive layer 125 may be coated on a resulting structure of the semiconductor substrate 100. The adhesive layer 125 may be a photosensitive polymer such as: an ultraviolet (UV) curing resin, which is one of an acryl group resin; an epoxy group resin, which is one of thermo-set resins; and a mixture of these resins. The adhesive layer 125 may have a thickness of about 10 μm-30 μm.

Referring to FIGS. 1 and 2C, portions of the adhesive layer 125 may be selectively removed to form an adhesive pattern 125a, which may enclose the effective pixel 105 in a region between the effective pixel 105 and the bonding pads 110. If the adhesive layer 125 is a photosensitive polymer as described above, the selectively removing portions of the adhesive layer 125 may be achieved by light-exposing and developing the adhesive layer.

Due to the forming of the adhesive pattern 125a, a residual material (not shown) of the adhesive layer 125 may exist on the effective pixel 105, e.g., on the protective layer 120. Because the residual material may decrease image quality of the image device, the residual material of the adhesive layer 125 may be removed through an ashing or descum process before a subsequent process is performed. Because the microlens 115 may be covered with the protective layer 120, the microlens 115 may be protected during the ashing or descum process. Also, the ashing or descum process may have an influence on the adhesive pattern 125a, but the amount of the residual material may be very small and the adhesive pattern 125a may have a thickness of about 10 μm-30 μm, so that any loss of the adhesive pattern 125a due to the ashing or descum process is trivial.

Referring to FIGS. 1 and 2D, a transparent cover 130 may be attached on each die determined to be normal in an electrical data sorting (EDS) test. The transparent cover 130 may be attached using a die bonder 135. In more detail, the die bonder 135 may vacuum the transparent cover 135 and align the transparent cover 135 with the effective pixel 105. The semiconductor substrate 100 may be maintained in an approximate temperature range of 10-100° C., the die bonder 135 may be maintained in an approximate temperature range of 100-300° C., and the aligned transparent cover 130 may be placed on the adhesive pattern 125a. If the semiconductor substrate 100 and the die bonder 135 are maintained at a temperature around 100° C., preliminary attaching may be performed simultaneously on each die with placing the transparent cover 130 on the adhesive pattern 125a. Here, the transparent cover 130 may be glass, infrared (IR), or a similar material filter; the IR filter blocks unnecessary light in an infrared wavelength band except light in a useful wavelength band utilized in a solid-state image sensing device.

Referring to FIG. 2E, a resulting structure of a semiconductor substrate 100 on which the transparent cover 130 is preliminarily attached may be hardened, so that the transparent cover 130 may be permanently attached on each die 101 of the semiconductor substrate 100. The hardening process may be performed in an oven of approximately 100-250° C. for about 30 minutes to 90 minutes. Because the hardening process may be performed over an entire semiconductor substrate 100, a plurality of transparent covers 130 may be collectively attached on the plurality of dies 101. Reference numeral 140 in FIG. 2E represents the hardening process in the oven.

Referring to FIG. 2F, the semiconductor substrate 100 may be sawed along each die 101.

According to example embodiments of the present invention, a resulting structure of the effective pixel 105, which includes the surface of the microlens 115, may be coated with the protective layer 120 before the forming of the adhesive layer utilized in attaching the transparent cover 130. The residual material may be removed without loss of the microlens 115 even when residual materials of the adhesive pattern 125a remain on the resulting structure of the effective pixel 105 when the adhesive pattern 125a is formed.

Also, the transparent cover 130 may be preliminarily attached using the die bonder 135 and permanently attached through curing in the oven, so that the transparent covers 130 may be collectively attached without using a costly wafer bonding apparatus for an extended period of time.

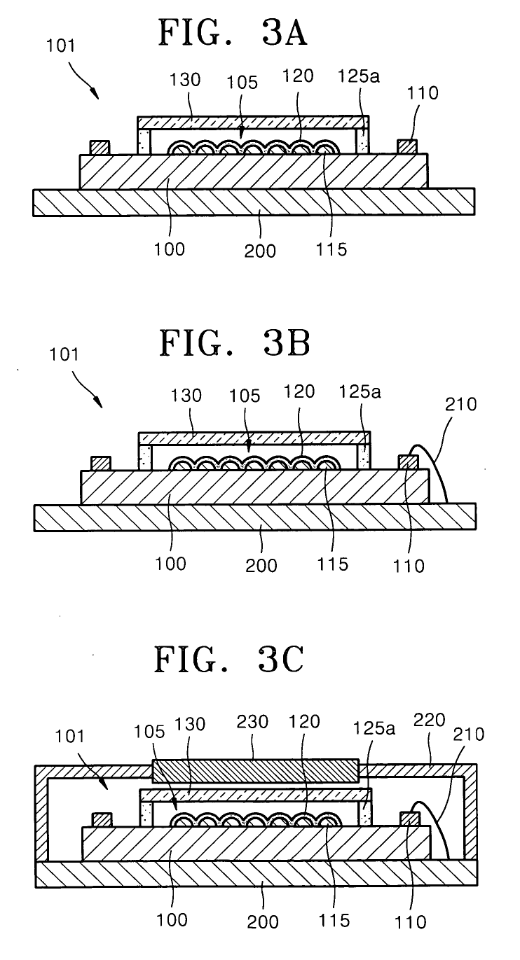

FIGS. 3A through 3C are diagrams illustrating sectional views for illustrating respective processes of a method of manufacturing an image sensor module according to example embodiments of the present invention.

Referring to FIG. 3A, a die 101, on which an effective pixel 105 may be coated with a protective layer 120 and a transparent cover 130 may be attached on a semiconductor substrate 100 using an adhesive pattern 125a, which is mounted on a PCB 200 using an adhesive member (not shown). A substrate as a chip carrier, in place of PCB 200, may be used for an image sensor package, such as a ceramic substrate in an alumina group, a plastic glass laminated substrate, a tape based substrate, or a flexible circuit board.

Referring to FIG. 3B, a bonding pad 110 of the die 101 may be electrically connected to the PCB 200 using a wire 210.

Referring to FIG. 3C, a lens holder 220 may be provided on the PCB 200 such that an effective pixel 105 of the die 101 is opened, and a lens 230 for establishing a light path is assembled in the lens holder 220.

Though not shown in the drawing, the PCB 200 may be separated by using a blade or sawing to form individual image sensor packages.

As the transparent cover 130 may be attached on the die 101 using the adhesive pattern 125a, the housing is not required for mounting the transparent cover 130, enabling the manufacture of an image sensor module having a smaller size and a slimmer profile.

Also, because the effective pixel 105 may be enclosed by the transparent cover 130 and the adhesive pattern 125a while the lens holder is provided, defects due to humidity, dust, and scratches may be prevented.

As described above, before attaching the transparent cover onto the region corresponding to the effective pixel, the surface of the resulting structure of the effective pixel (including the surface of the microlens) may be coated with the protective layer and then the adhesive pattern for attaching the transparent cover may be formed. Even when the remainder of the adhesive pattern remains on the effective pixel during the forming of the adhesive pattern, the remainder of the adhesive pattern may be selectively removed without damaging the microlens. It is possible to prevent a defective display operation and defective sensing operation of the image device due to remaining particles.

Also, the transparent covers may be simultaneously and permanently attached onto each die by preliminarily attaching the transparent covers onto the respective dies and then hardening the entire portion of the semiconductor substrate. The transparent covers may be simultaneously attached onto the semiconductor substrate within a short time without using the wafer bonder device for an extended period of time. In example embodiments of the present invention, good-quality dies are determined by performing the EDS process before the attachment of the transparent covers. Sensing failure and displaying failure of the image sensor may be avoided due to the protection by the transparent cover.

Also, because the transparent covers are attached onto the semiconductor substrate (in other words, the respective dies) without using the housing, a smaller and thinner module may be obtained.

The foregoing is illustrative of example embodiments of the present invention and is not to be construed as limiting thereof. Although a few example embodiments of the present invention have been described, those skilled in the art will readily appreciate that many modifications are possible in example embodiments without materially departing from the novel teachings and advantages of the present invention. Accordingly, all such modifications are intended to be included within the scope of this invention as defined in the claims. In the claims, means-plus-function clauses are intended to cover the structures described herein as performing the recited function, and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A method of manufacturing an optical device, the method comprising:
providing a semiconductor substrate where an image device is formed;
forming a protective layer on the image device;
forming an adhesive pattern on the semiconductor substrate; and
attaching a cover on the semiconductor substrate using the adhesive pattern.

2. The method of claim 1, wherein attaching the cover includes:
adhering the cover onto the adhesive pattern; and
curing the adhesive pattern.

3. The method of claim 2, wherein the semiconductor substrate comprises a plurality of image devices.

4. The method of claim 3, wherein attaching the cover comprises individually attaching a single image device with a single cover.

5. The method of claim 3, wherein attaching the cover comprises collectively attaching a plurality of image devices with a plurality of covers.

6. The method of claim 5, wherein each of the plurality of the image devices comprises a solid-state image sensing device including a charge coupled device (CCD) or a CMOS image sensor (CIS).

7. The method of claim 3, wherein each of the plurality of image devices includes a light-receiving device upon which a microlens is placed.

8. The method of claim 7, wherein forming the protective layer includes depositing a transparent layer along a surface of a microlens of each of the plurality of image devices.

9. The method of claim 8, wherein the protective layer is an oxide layer deposited in a temperature range of 100-200° C.

10. The method of claim 9, wherein the oxide layer is formed using chemical vapor deposition (CVD) or atomic layer deposition (ALD).

11. The method of claim 7, further comprising, after forming the protective layer on each of the plurality of image devices, etching a portion of the protective layer such that the protective layer exists on only each microlens.

12. The method of claim 1, wherein forming the adhesive pattern comprises:
forming an adhesive layer on a resulting structure of the semiconductor substrate where the protective layer is formed; and
patterning the adhesive layer.

13. The method of claim 12, wherein the adhesive layer has a thickness of 10 μm-30 μm.

14. The method of claim 12, wherein the adhesive layer comprises a photosensitive polymer.

15. The method of claim 14, wherein pattering the adhesive layer comprises:
exposing a portion of the adhesive layer; and
developing the exposed portion.

16. The method of claim 12, further comprising, after forming the adhesive pattern, removing an adhesive pattern residual material remaining on the protective layer.

17. The method of claim 16, wherein removing the adhesive pattern residual material comprises removing the adhesive pattern residual material using an ashing or descum process.

18. The method of claim 1, further comprising, between forming the adhesive pattern and attaching the cover, inspecting whether a die including the image device has been normally formed.

19. The method of claim 2, wherein the cover is transparent, adhering the transparent cover includes preliminarily attaching the transparent cover for a die including the image device, and curing the transparent cover includes permanently attaching the preliminarily attached transparent cover.

20. The method of claim 18, wherein preliminarily attaching the transparent cover includes:
aligning the transparent cover with the image device of the die using a die bonder; and
placing the aligned transparent cover on the adhesive pattern.

21. The method of claim 20, wherein during the placing of the transparent cover, the substrate is maintained in a temperature range of 10-100° C., and the transparent cover is maintained in a temperature range of 100-300° C.

22. The method of claim 19, wherein permanently attaching the transparent cover on the semiconductor substrate includes inserting the semiconductor substrate, on which the transparent cover is preliminarily attached, into an oven to cure the semiconductor substrate.

23. The method of claim 22, wherein curing the cover is performed in a temperature range of 100-250° C. for 30-90 minutes.

24. The method of claim 1, wherein the semiconductor substrate has a plurality of dies including an image device and a plurality of bonding pads arranged around the image device,
the protective layer selectively covers the image device, and
the adhesive pattern encloses the image device, the method further comprising:
removing a residual material of the adhesive pattern remaining on the protective layer, and
attaching the transparent cover on a normal die of the plurality of dies.

25. The method of claim 24, wherein attaching the transparent cover includes adhering the transparent cover onto the adhesive pattern; and
hardening the semiconductor substrate to collectively and permanently attach a plurality of transparent covers.

26. The method of claim 24, wherein the image device comprises a light-receiving device upon which a microlens is placed.

27. The method of claim 26, wherein forming the protective layer includes depositing a transparent layer along the surface of the microlens on the image device.

28. The method of claim 28, wherein the transparent layer is an oxide layer deposited in a temperature range of 100-200° C.

29. The method of claim 24, wherein the forming of the protective layer to selectively cover the image device comprises:
forming a protective layer on a resulting structure of the semiconductor substrate; and
etching a portion of the protective layer such that the protective layer exists on only the image device.

30. The method of claim 24, wherein forming the adhesive pattern includes:
forming an adhesive layer on a resulting structure of the semiconductor substrate where the protective layer is formed; and
patterning the adhesive layer to enclose the image device between the image device and the plurality of bonding pads.

31. The method of claim 30, wherein the adhesive layer has a thickness of 10 μm-30 μm.

32. The method of claim 30, wherein the adhesive layer comprises a photosensitive polymer.

33. The method of claim 21, wherein the patterning of the adhesive layer comprises:
exposing a portion of the adhesive layer; and
developing the exposed portion.

34. The method of claim 24, wherein removing the residual material comprises removing the residual material using an ashing or descum process.

35. The method of claim 24, wherein adhering to the transparent cover comprises:
aligning the transparent cover with an image device of the die using a die bonder; and
placing the aligned transparent cover on the adhesive pattern.

36. The method of claim 33, wherein in the placing of the transparent cover, the substrate is maintained in a temperature range of 10-100° C., and the transparent cover is maintained in a temperature range of 100-200° C.

37. The method of claim 23, wherein the hardening of the semiconductor substrate comprising hardening the semiconductor substrate in an oven maintaining a temperature range of 100-250° C. for 30-90 minutes.

38. A method of manufacturing an optical device module comprising:
performing the method of claim 24;
sawing the semiconductor substrate into individual dies;
mounting each die on a substrate;
electrically connecting each die with the substrate; and
installing a lens on the substrate.

39. The method of claim 38, wherein the protective layer comprises a low temperature oxide layer formed in a temperature range of 100-200° C.

40. The method of claim 38, wherein the adhesive pattern comprises a photosensitive polymer.

41. The method of claim 38, further comprising, between forming the adhesive pattern and attaching the transparent cover, removing a residual material of the adhesive pattern on the protective layer.

42. The method of claim 38, wherein attaching the transparent cover comprises:
attaching the transparent cover to the image device using a die bonder; and
hardening a resulting structure of the semiconductor substrate in a temperature range of 100-200° C.
